(19) United States
(12) Patent Application Publication
(10) Pub. No.: US 2011/0008718 A1
(43) Pub. Date: Jan. 13, 2011

(54) SUBSTRATE CONVEYANCE METHOD AND SUBSTRATE CONVEYANCE DEVICE, EXPOSURE APPARATUS USING SAME, AND DEVICE MANUFACTURING METHOD

(75) Inventor: Hiroyuki Miyazaki, Utsunomiya-shi (JP)

Correspondence Address: CANON U.S.A. INC. INTELLECTUAL PROPERTY DIVISION, 15975 ALTON PARKWAY, IRVINE, CA, 92618-3731, US

(73) Assignee: CANON KABUSHIKI KAISHA, Tokyo (JP)

(21) Appl. No.: 12/827,584

(22) Filed: Jun. 30, 2010

(30) Foreign Application Priority Data
Jul. 10, 2009 (JP) 2009-164243

(51) Int. Cl. G03F 7/20; G03B 27/60

(52) U.S. Cl. 430/30; 355/73; 355/77

(57) ABSTRACT

The substrate conveyance method of the present invention includes an adjusting step further includes a suction time monitoring sub-step in which the suction pressure of a suction mechanism is upward raised to a predetermined threshold value after a lifting of a hand from a standby position on a mounting section is initiated in a vacuum suction state and its driving time is monitored, an adjustment determining sub-step of determining whether or not an adjustment of a receiving position is necessary based on a monitor time period that has been obtained by the suction time monitoring sub-step, and a position setting sub-step of automatically setting the receiving position to the position at which a tolerance range is satisfied, if it has been determined in the adjustment determining sub-step that the monitor time period and the suction pressure of the suction mechanism are not in a predetermined tolerance range.

### BACKGROUND OF THE INVENTION

1. Field of the Invention

The present invention relates to a substrate conveyance method and a substrate conveyance device, an exposure apparatus using the same, and a device manufacturing method.

2. Description of the Related Art

An exposure apparatus is an apparatus that transfers a pattern of an original (reticle or mask) onto a photosensitive substrate (e.g., wafer, glass plate, and the like, where the surface thereof is coated with a resist layer) via a projection optical system in a lithography process in a manufacturing process of a semiconductor element, a liquid crystal display element, and the like. A substrate stage and a substrate conveyance device constituting the exposure apparatus are typically installed on two different reference platforms. In the exposure apparatus disclosed in Japanese Patent Laid-Open No. 2-309624, a substrate conveyance robot is installed separately from a structure that supports a substrate stage, so that vibration generated by a conveyance section is not transmitted to an exposure body.

In this case, in the step of installing an exposure apparatus, a misalignment may occur between the substrate receiving position used by a substrate conveyance device and the substrate mounting section of a substrate stage. In light of the above, in order to ensure that the substrate conveyance device successfully receives a substrate from the substrate stage, adjustment of the receiving position is implemented for each exposure apparatus installation. Likewise, it is contemplated that the respective reference platforms may change over time due to the subsidence of the floor on which the reference platform of the exposure apparatus is installed. Hence, for example, re-adjustment of the receiving position is implemented on an annual basis. For this re-adjustment, human intervention is required for the determination of whether re-adjustment of the receiving position is necessary and the implementation of re-adjustment operations.

However, since the aforementioned re-adjustment operations require human intervention, down time occurs in the operation of the exposure apparatus, resulting in an decrease in the processing speed of the entire exposure apparatus. On the other hand, if re-adjustment operations are not implemented, the receiving position may differ from a desired position. Consequently, there is a risk where substrates may interfere with each other at the receiving position between the substrate conveyance device and the substrate stage.

### SUMMARY OF THE INVENTION

Accordingly, the present invention provides a substrate conveyance method and a substrate conveyance device for installing a substrate conveyance device and a substrate stage on two different reference platforms and adjusting the receiving position automatically if a misalignment occurs on the receiving position of a substrate.

According to an aspect of the present invention, a substrate conveyance method for conveying a substrate to a mounting section based on the command of a control system is provided which is carried out by a substrate conveyance device including a supporting mechanism including a hand for holding the substrate by a suction mechanism and a support section for movably supporting the hand, and a control system for controlling the operation of the supporting mechanism, the substrate conveyance method including an adjusting step of adjusting the receiving position of the substrate by the control system, when the supporting mechanism and the mounting section are installed on two different reference platforms, wherein the adjusting step further includes a suction time monitoring sub-step in which the suction pressure of the suction mechanism is upward raised to a predetermined threshold value after the lifting of the hand from the standby position on the mounting section is initiated in a vacuum suction state and its driving time is monitored; an adjustment determining sub-step of determining whether or not the adjustment of the receiving position is necessary based on the monitor time period that has been obtained by the suction time monitoring sub-step; and a position setting sub-step of automatically setting the receiving position to the position at which a tolerance range is satisfied if it has been determined in the adjustment determining sub-step that the monitor time period and the suction pressure of the suction mechanism are not in a predetermined tolerance range.

According to the present invention, the receiving position of a substrate may be adjusted without human intervention, resulting in the reduction of down time for an apparatus, and a further increase in the productivity of the semiconductor manufacturing process.

Further features of the present invention will become apparent from the following description of exemplary embodiments with reference to the attached drawings.

### BRIEF DESCRIPTION OF THE DRAWINGS

FIG. 1 is a schematic view illustrating the configuration of the body portion of an exposure apparatus according to an embodiment of the present invention.

FIG. 2 is a schematic view illustrating the configuration of a device manufacturing system according to an embodiment of the present invention.

FIG. 3A is a view illustrating the operation of a conveyance device according to an embodiment of the present invention.

FIG. 3B is a view illustrating the operation of a conveyance device according to an embodiment of the present invention.

FIG. 3C is a view illustrating the operation of a conveyance device according to an embodiment of the present invention.

FIG. 3D is a view illustrating the operation of a conveyance device according to an embodiment of the present invention.

FIG. 3E is a view illustrating the operation of a conveyance device according to an embodiment of the present invention.

FIG. 4 is a flowchart illustrating the position adjustment sequence to be carried out by a control system.

FIG. 5 is a view illustrating the relationship between the driving time of a substrate conveyance device and the suction pressure of a hand suction mechanism according to an embodiment of the present invention.

### DESCRIPTION OF THE EMBODIMENTS

Hereinafter, preferred embodiments of the present invention will now be described with reference to the accompanying drawings.

### (Exposure Unit)

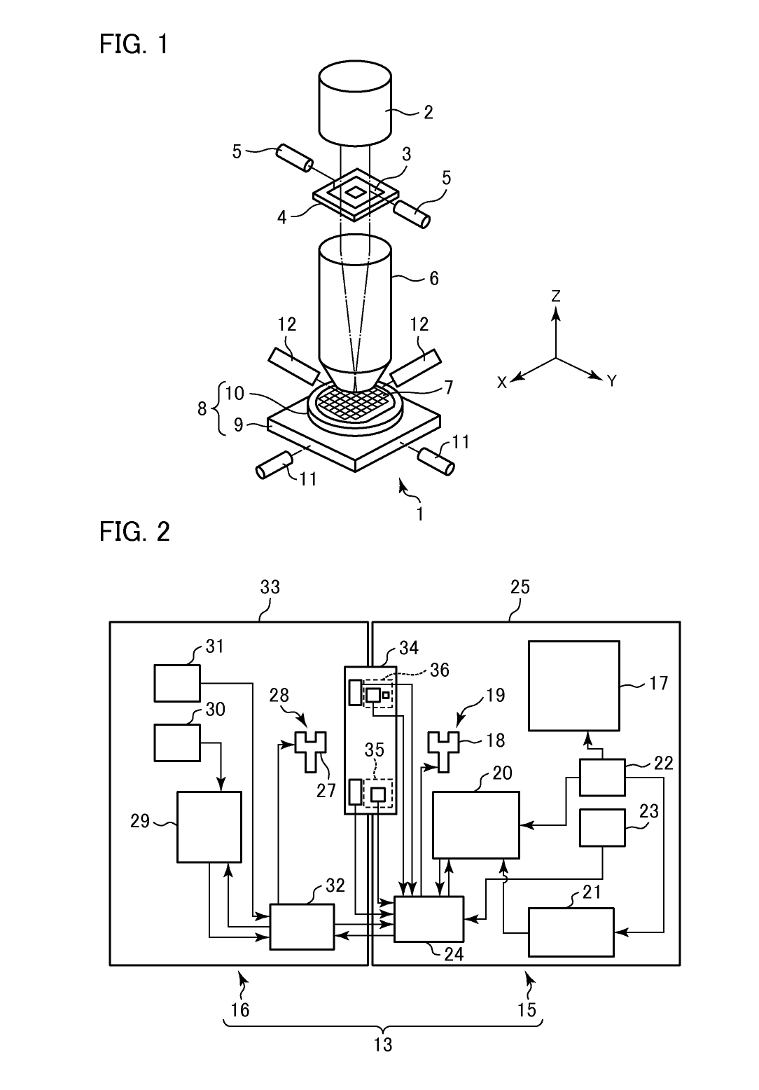

FIG. 1 is a schematic view illustrating the body portion (hereinafter referred to as “exposure unit”) of an exposure apparatus according to an embodiment of the present invention. An exposure unit 1 is an apparatus that exposes a reticle pattern onto a wafer by a step-and-scan method or a step-and-repeat method, but the exposure method is not particularly limited. For the purpose of explanation, in FIG. 1, the Z axis is aligned parallel to the optical axis of the projection optical system constituting the exposure unit 1, the Y axis is aligned in the scanning direction of a reticle (original) and a wafer (substrate) during scanning exposure in the plane perpendicular to the Z axis, and the X axis is aligned in the non-scanning direction perpendicular to the Y axis. The exposure unit 1 includes an illumination optical system 2, a reticle stage 4 that holds a reticle 3 in which a pattern has been formed, a reticle position measuring unit 5, a projection optical system 6, and a substrate stage system 8 that positions a wafer 7 to which a photoresist is applied.

The illumination optical system 2 introduces illumination light through a beam line from a built-in light source (an electric-discharge lamp such as an extra high pressure mercury lamp) or a light source device (light source section) provided separately from the exposure unit 1, and generates slit light by various lenses and stops to illuminate the reticle 3 from above. The reticle stage system 4 is a stage that is movable in the X and Y directions. The reticle position measuring unit 5 is a device that measures the position of the reticle 3. The projection optical system 6 contracts and projects the pattern of the reticle 3 onto the wafer 7 at a predetermined magnification (e.g., 4:1). Also, the substrate stage system 8 includes a XY stage 9 that can move the wafer 7 in the X and Y directions, and a Z stage 10 that can move the wafer 7 in the Z direction. Furthermore, the exposure unit 1 includes a laser interferometer 11 that measures the position of the XY stage 9 in the X and Y directions, and a focus unit 12 that measures the position of the wafer 7 in the Z direction.

### (Device Manufacturing System)

FIG. 2 is a schematic view (plan view) illustrating a device manufacturing system according to an embodiment of the present invention. A device manufacturing system 13 consists of an exposure apparatus 15 having the exposure unit 1 shown in FIG. 1, and a coating/developing apparatus 16.

The exposure apparatus 15 includes an the exposure processing section 17, which includes the exposure unit 1, a first conveyance unit 19 including a hand 18 that holds a wafer, i.e., an object to be treated, a control section 20 that controls the exposure apparatus 15, and an input/output device 21 which is a user interface. Furthermore, the exposure apparatus 15 includes a main power supply 22, an auxiliary power supply 23, and a first conveyance control section 24 that controls the first conveyance unit 19. Each of these components is disposed within an exposure chamber 25. Here, the main power supply 22 provides power at least to the exposure processing section 17, the control section 20, and the input/output device 21. In contrast, the auxiliary power supply 23 provides power to the first conveyance control section 24. The auxiliary power supply 23 is configured to replace the main power supply 22 to continue power supply when power supply to an object that is supplied with power by the main power supply 22 is interrupted. More specifically, the auxiliary power supply 23 may be arranged to include, for example, a secondary battery. In this case, the auxiliary power supply 23 charges the secondary battery by electrical power provided from the main power supply 22 when the main power supply 22 is normal. On the other hand, the object to which power is supplied is powered by the secondary battery when the power supply provided by the main power supply 22 is interrupted by an abnormality or power failure of the main power supply 22.

The coating/developing apparatus 16 includes an application/development section 26, which includes an application/development unit that serves to apply a photoresist onto a wafer and to develop the exposed wafer, a second conveyance unit 28 including a hand 27 that holds a wafer, and a control section 29 that controls the coating/developing apparatus 16. Furthermore, the coating/developing apparatus 16 includes a main power supply 30, an auxiliary power supply 31, and a second conveyance control section 32 that controls the second conveyance unit 28. Each of these components is disposed within an application/development chamber 33. Note that the operations of the main power supply 30 and the auxiliary power supply 31 are the same as those of the main power supply 22 and the auxiliary power supply 23 that are provided in the exposure apparatus 15 described above.

Also, the device manufacturing system 13 includes a transfer station 34 that transfers a wafer between the exposure apparatus 15 and the coating/developing apparatus 16. First, the second conveyance unit 28 conveys a photoresist-coated wafer to a carrying-in section 35 in the transfer station 34. The first conveyance unit 19 receives the wafer that has been conveyed in the carrying-in section 35 and conveys the wafer to the exposure processing section 17. After the completion of exposure processing, the first conveyance unit 19 conveys the wafer from the exposure processing section 17 to a carrying-out section 36 in the transfer station 34. The second conveyance unit 28 then receives the wafer that has been conveyed from the carrying-out section 36 and conveys the wafer to the application/development section 26 for development processing. Note that the first conveyance unit 19 may convey a wafer to the XY stage 9 shown in FIG. 1 via a wafer alignment unit (not shown). Furthermore, the exposure apparatus 15 may include a plurality of wafer conveyance units.

### (Substrate Conveyance Device)

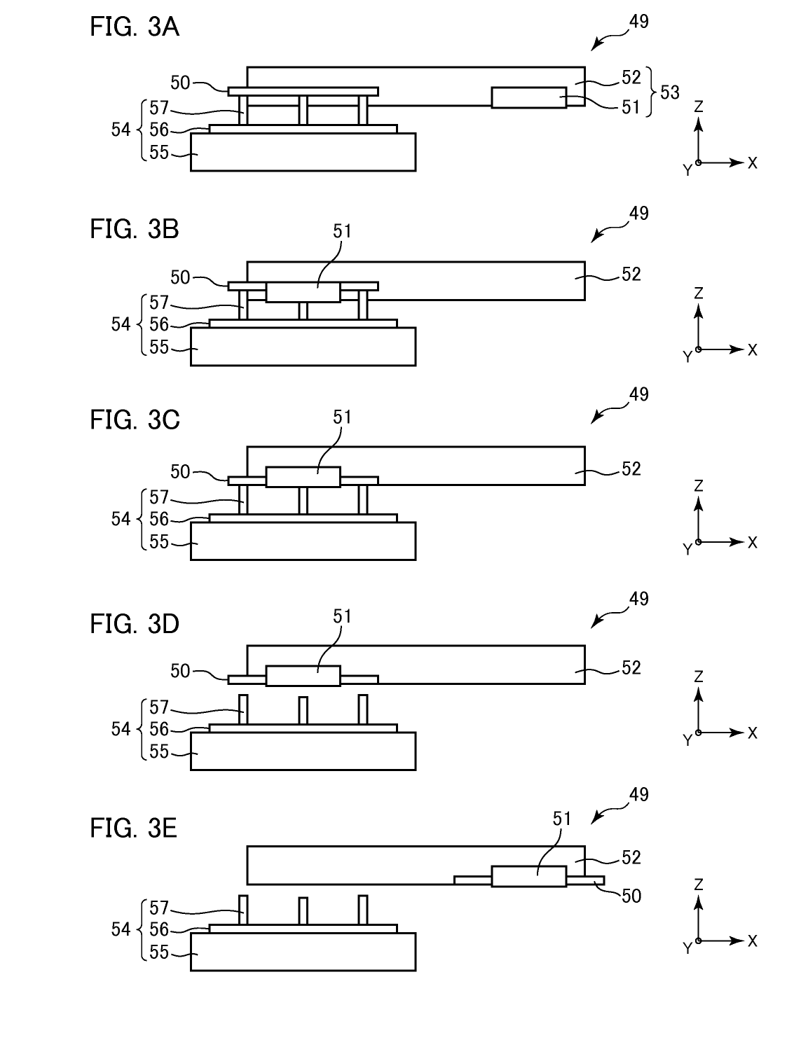

FIGS. 3A to 3E are substrate conveyance devices according to an embodiment of the present invention, and are schematic views illustrating the operation to be performed when the substrate conveyance device receives a wafer from a substrate stage. A substrate conveyance device 49 includes a supporting mechanism 53 having a hand 51 that holds a wafer 50 and a support section 52 that is drivable in the three X, Y, and Z directions while movably supporting the hand 51 in the horizontal direction, and a control system (not shown) that controls the supporting mechanism 53. Here, the hand 51, the supporting mechanism 53, and the control system shown in FIGS. 3A to 3E may be adopted to the hand 18, the first conveyance unit 19, and the first conveyance control section 24 (or the control section 20) shown in FIG. 2, respectively. Also, the hand 51 includes a suction mechanism (not shown) that holds by vacuum the wafer 50 by controlling pressure. Furthermore, a wafer mounting section 54 within an exposure unit includes a substrate stage 55, a chuck 56 provided on the substrate stage 55, and three push-up pins (transfer support section) 57. Here, the substrate stage 55 shown in FIGS. 3A to 3E may be adopted to the substrate stage system 8 within the exposure unit 1, shown in FIG. 1, which is disposed within the exposure processing section 17 shown in FIG. 2. It should be noted that the supporting mechanism 53 and the wafer mounting section 54 are installed on the respectively independent reference platforms.

First, in FIG. 3A, the wafer 50 is held on the push-up pins 57. At this time, a transfer operation is not initiated by the substrate conveyance device 49. Next, in FIG. 3B, in order to receive the wafer 50 by using the substrate conveyance device 49, the control system drives the support section 52, drives the hand 51 in the X and Y directions, and causes the hand 51 to wait at the bottom surface of the wafer 50, i.e., the standby position on the wafer mounting section. At this time, the hand 51 is in a waiting state while avoiding the push-up pins 57 so that the hand 51 does not interfere with the push-up pins 57. Next, in FIG. 3C, the control system controls the suction state of the hand 51 to be in a vacuum suction state. Thereafter, the control system raises the hand 51 in the Z direction integrally with the supporting mechanism 53. Here, the hand 51 is upward raised from the bottom surface position at which the wafer 50 is not held, so that the Z directional position at which the pressure value of the suction mechanism provided with the hand 51 exceeds a predetermined threshold value, i.e., the position at which the holding by suction of the wafer 50 is executed becomes the receiving position of the wafer 50. Next, in FIG. 3D, until the space for avoiding any interference with the push-up pins 57 is ensured when the hand 51 is driven from the receiving position of the wafer 50 in the X and Y directions, the control system continues the upward raising of the supporting mechanism 53 while holding the wafer 50. Then, in FIG. 3E, the substrate conveyance device 49 drives the hand 51 in the X direction, and further drives the entire supporting mechanism 53 in the X, Y, and Z directions as appropriate, whereby the substrate conveyance device 49 conveys the wafer 50 to the carrying-out section 36 provided within the transfer station 34 shown in FIG. 2.

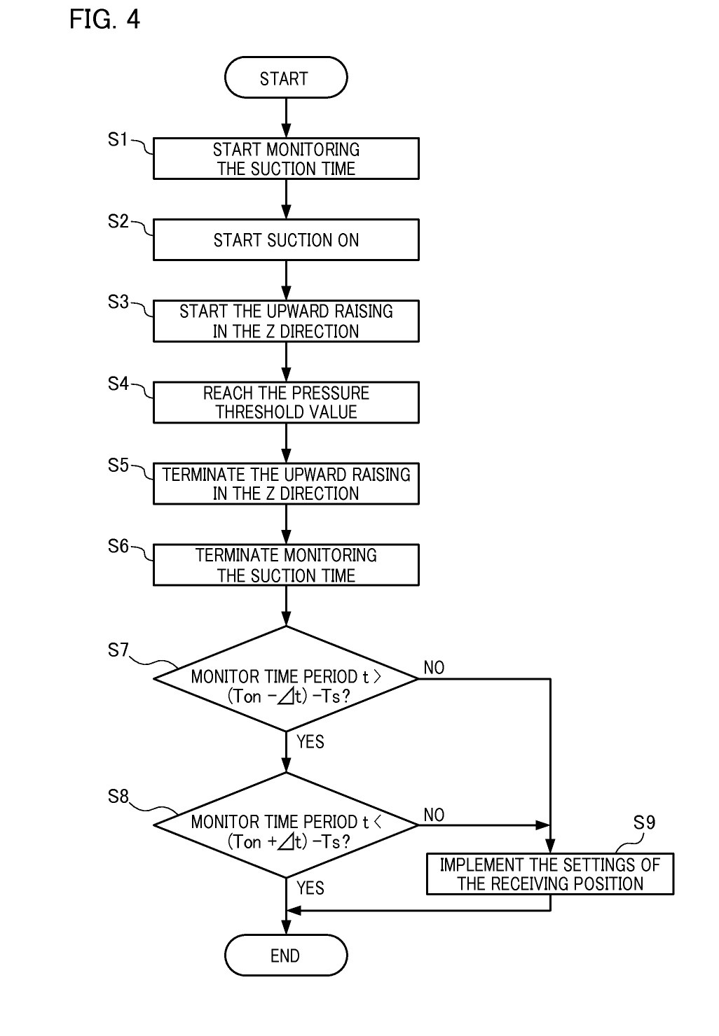

Next, the substrate conveyance method of the present invention will now be described. FIG. 4 is a flowchart illustrating the position adjustment sequence of the wafer receiving position to be carried out by the control system according to an embodiment of the present invention. It should be noted that the flowchart shown in FIG. 4 is a view illustrating the operation commands to be executed by the control system in FIGS. 3B, 3C, and 3D. It is desirable that the position adjustment sequence be executed when a wafer is being conveyed in a normal way.

First, as shown in FIG. 3B, the control system confirms that the hand 51 is made waiting at the bottom surface of the wafer 50, and then starts monitoring the suction time (step S1). Next, as shown in FIG. 3C, the control system controls the suction state of the hand 51 to be in a vacuum suction state (step S2). Next, the control system upwardly raises the hand 51, which is maintained in a vacuum suction state, in the Z direction integral with the supporting mechanism 53 (step S3). Then, the hand 51 reaches to the Z directional position at which the pressure threshold value is exceeded, i.e., the receiving position of the wafer 50 while being raised (step S4). Next, as shown in FIG. 3D, the control system confirms that the space for avoiding any interference with the push-up pins 57 is ensured when the hand 51 is driven in the X and Y directions, and then completes the upward raising of the supporting mechanism 53 (step S5). Here, after completion of the upward raising, the control system terminates the monitoring of the suction time, and stores the monitor time period t ranging from the monitor start in step S1 to the monitor end (step S6). As described above, the steps S1 to S6 are an example of the suction time monitoring sub-step (suction time monitoring processing) of the present invention.

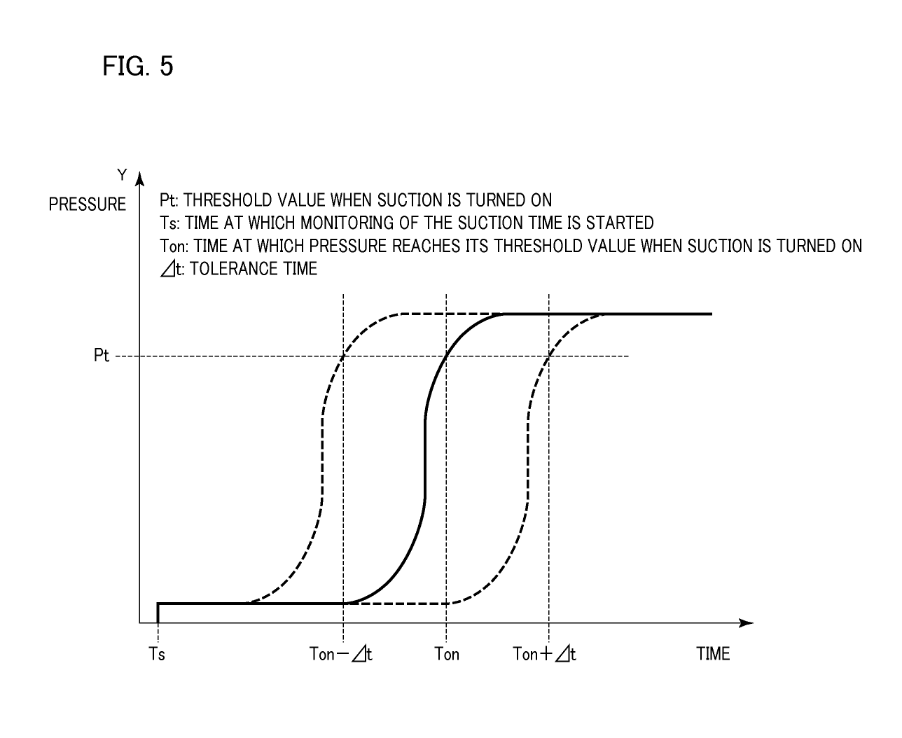

Next, the control system determines whether or not the adjustment of the receiving position of the wafer 50 is necessary based on the monitor time period t that has been stored in step S6. First, a description will now be given as to the relationship between the driving time of the substrate conveyance device 49 and the suction pressure offered by the suction mechanism of the hand 51 when the substrate conveyance device 49 receives the wafer 50 from the wafer mounting section 54. FIG. 5 is a graphical representation of the variation of the suction pressure with respect to the driving time. In FIG. 5, the X axis is the driving time of the substrate conveyance device 49, and the Y axis is the suction pressure of the hand 51. Also, the notation “Pt” refers to a predetermined pressure threshold value, and the notation “Ts” refers to the time at which monitoring of the suction time is started. The notation “Ton” refers to the time at which pressure reaches its threshold value, i.e., the time at which the hand 51 is positioned at the wafer-receiving position. The notation “Δt” refers to the tolerance time for variation of Ton, which is a predetermined value. This Δt may be obtained by simulations, actual measurements, and the like.

First, the control system calculates the value of (Ton−Ts), and manages a time required for steps S1 to S6. Here, the upward raising quantity in steps S1 to S6 is always constant, unless each reference platform, on which the substrate conveyance device 49 and the wafer mounting section 54 are installed, fluctuates over time in the Z direction. In other words, the control system manages the upward raising quantity using the value of (Ton−Ts), whereby the control system can recognize and determine the receiving position of the wafer 50 from the value of (Ton−Ts). Here, in further consideration of the value Δt, the value of ((Ton−Δt)−Ts) denotes the case where the upward raising quantity is lower than the expected value. For example, it is assumed that the reference platform on the wafer mounting section 54 is subjected to subsidence. On the other hand, the value of ((Ton+Δt)−Ts) denotes the case where the upward raising quantity is greater than the expected value. For example, it is assumed that the reference platform on the substrate conveyance device 49 side is subsided. Hence, the control system determines the value of ((Ton±Δt)−Ts) to be a threshold value in which the substrate conveyance device 49 can successfully receive the wafer from the wafer mounting section 54. In other words, when the monitor time period t is in the range of t>((Ton−Δt)−Ts), the subsidence of the reference platform either on the substrate conveyance device 49 or on the wafer mounting section 54 is within the assumption. In this case, the control system determines that the wafer 50 is receivable (YES in step S7). On the other hand, when the monitor time period t is in the range of t<((Ton+Δt)−Ts), the subsidence of the reference platform either on the substrate conveyance device 49 or on the wafer mounting section 54 is likewise within the assumption, and the control system thereby determines that the wafer 50 is receivable (YES in step S8). As described above, the steps S7 and S8 are an example of the adjustment determining sub-step (adjustment determining processing) of the present invention.

Next, when the control system determines in steps S7 and S8 that the subsidence of each reference platform is outside the assumption based on the aforementioned determination formula (NO in steps S7 and S8), in other words, when the monitor time period t and the suction pressure do not satisfy a predetermined tolerance range, the control system implements the settings of the receiving position (step S9). In step S9, adjustment of the receiving position is made by implementing the operations illustrated in FIGS. 3A, 3B, and 3C repeatedly. More specifically, first, the control system executes processing for determining the receiving position of the wafer 50 as shown in steps S2 to S4 in FIG. 4. In order to enhance the Z position determination accuracy during determination processing, it is desirable that the speed of the upward raising of the hand 51 be slowed down. Next, the control system again executes processing for determining the receiving position of the wafer 50 as shown in steps S2 to S4 in FIG. 4 at a steady speed (conveyance processing speed for normal processing). Here, the control system continues resetting the driving time of the substrate conveyance device 49 until the wafer 50 reaches the Z position that has been determined by determination processing in advance as the value of Ton (second driving time) to thereby set a new receiving position. For example, when the monitor time period t to be used in determination processing at a steady speed is in the range of t<((Ton−Δt)−Ts), the setting change may be made such that the control system recognizes the value of (Ton−Δt) as a new value of Ton. As described above, the step S9 is an example of the position setting sub-step (position setting processing) of the present invention.

As described above, according to the substrate conveyance device of the present invention, the receiving position of a wafer may be automatically adjusted based on information consisting of the driving time of the substrate conveyance device and the suction pressure of the hand when the substrate conveyance device receives the wafer from the wafer mounting section. Hence, when the reference platform changes over time due to the initial adjustment of the receiving position upon installation of the exposure apparatus, the subsidence of the floor on which the reference platform of the exposure apparatus is installed, and the like, the receiving position of a substrate may be adjusted without human intervention, resulting in the reduction of down time for an exposure apparatus, and a further increase in the productivity of the semiconductor manufacturing process.

For example, when the adjustment range of the receiving position of a wafer is limited due to the structure of the exposure apparatus, a limit sensor may be separately installed to perform monitoring by the control system in order to prevent interference between the substrate conveyance device and the wafer mounting section. In the foregoing embodiment, since the control system stores the monitor time period, the control system may also determine the timing, at which an adjustment of the receiving position is implemented, automatically as appropriate based on the receiving determination of the wafer during normal exposure processing.

### (Device Manufacturing Method)

Next, a method of manufacturing a device (semiconductor device, liquid crystal display device, etc.) as an embodiment of the present invention is described. The semiconductor device is manufactured through a front-end process in which an integrated circuit is formed on a wafer, and a back-end process in which an integrated circuit chip is completed as a product from the integrated circuit on the wafer formed in the front-end process. The front-end process includes a step of exposing a wafer coated with a photoresist to light using the above-described exposure apparatus of the present invention, and a step of developing the exposed wafer. The back-end process includes an assembly step (dicing and bonding), and a packaging step (sealing). The liquid crystal display device is manufactured through a process in which a transparent electrode is formed. The process of forming a plurality of transparent electrodes includes a step of coating a glass substrate with a transparent conductive film deposited thereon with a photoresist, a step of exposing the glass substrate coated with the photoresist to light using the above-described exposure apparatus, and a step of developing the exposed glass substrate. The device manufacturing method of this embodiment has an advantage, as compared with a conventional device manufacturing method, in at least one of performance, quality, productivity and production cost of a device.

While the embodiments of the present invention have been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-164243 filed Jul. 10, 2009 which is hereby incorporated by reference herein it its entirety.

What is claimed is:

1. A substrate conveyance method for conveying a substrate to a mounting section based on the command of a control system, which is carried out by a substrate conveyance device comprising a supporting mechanism comprising a hand for holding the substrate by a suction mechanism and a support section for movably supporting the hand, and the control system for controlling the operation of the supporting mechanism, the substrate conveyance method comprising:
an adjusting step of adjusting the receiving position of the substrate by the control system, when the supporting mechanism and the mounting section are installed on two different reference platforms,
wherein the adjusting step further comprises:
a suction time monitoring sub-step in which the suction pressure of the suction mechanism is upward raised to a predetermined threshold value after the lifting of the hand from the standby position on the mounting section is initiated in a vacuum suction state and its driving time is monitored;
an adjustment determining sub-step of determining whether or not the adjustment of the receiving position is necessary based on the monitor time period that has been obtained by the suction time monitoring sub-step; and
a position setting sub-step of automatically setting the receiving position to a position at which a tolerance range is satisfied, if it has been determined in the adjustment determining sub-step that the monitor time period and the suction pressure of the suction mechanism are not in a predetermined tolerance range.

2. The substrate conveyance method according to claim 1, wherein a process similar to the suction time monitoring sub-step measures a second driving time being taken when the speed of the upward raising speed is slower than that employed for normal processing, and the position setting sub-step sets the receiving position based on the second driving time.

3. The substrate conveyance method according to claim 1, wherein the adjusting step is executed when the substrate is conveyed in a normal way.

4. A substrate conveyance device comprising a supporting mechanism comprising a hand for holding a substrate by a suction mechanism and a support section for movably supporting the hand, and a control system for controlling the operation of the supporting mechanism,
wherein, when the supporting mechanism and a mounting section are installed on two different reference platforms, the control system executes a position adjustment sequence for the execution of a suction time monitoring processing in which the suction pressure of the suction mechanism is upward raised to a predetermined threshold value after the lifting of the hand from a standby position on the mounting section is initiated in a vacuum suction state and its driving time is monitored; an adjustment determining processing of determining whether or not the adjustment of the receiving position of the substrate is necessary based on the monitor time period that has been obtained by the suction time monitoring processing; and a position setting processing of automatically setting the receiving position to the position at which a tolerance range is satisfied if it has been determined in the adjustment determining processing that the monitor time period and the suction pressure of the suction mechanism are not in a predetermined tolerance range.

5. The substrate conveyance device according to claim 4, wherein a process similar to the suction time monitoring sub-step measures a second driving time being taken when the speed of the upward raising speed is slower than that employed for normal processing, and the position setting processing sets the receiving position based on the second driving time.

6. The substrate conveyance device according to claim 4, wherein the position adjustment sequence is executed when the substrate is conveyed in a normal way.

7. An exposure apparatus comprising:
an illumination optical system that illuminates a reticle with light from a light source section;
a reticle stage system that is movable with the reticle mounted thereon;
a projection optical system that guides light from the reticle to a substrate;
a substrate stage system that is movable with the reticle mounted thereon; and
a substrate conveyance device that conveys the substrate to the substrate stage system,
wherein the substrate conveyance device comprises a supporting mechanism comprising a hand for holding the substrate by a suction mechanism and a support section for movably supporting the hand, and a control system for controlling the operation of the supporting mechanism, and
wherein, when the supporting mechanism and a mounting section are installed on two different reference platforms, the control system comprises a position adjustment sequence for the execution of an suction time monitoring process in which the suction pressure of the suction mechanism is upward raised to a predetermined threshold value after the lifting of the hand from the standby position on the mounting section is initiated in a vacuum suction state and its driving time is monitored; an adjustment determining processing of determining whether or not the adjustment of the receiving position of the substrate is necessary based on the monitor time period that has been obtained by the suction time monitoring processing; and a position setting processing of automatically setting the receiving position to the position at which a tolerance range is satisfied, if it has been determined in the adjustment determining processing that the monitor time period and the suction pressure of the suction mechanism are not in a predetermined tolerance range.

8. A device manufacturing method comprising the steps of:
exposing a substrate using an exposure apparatus; and
developing the substrate,
wherein the exposure apparatus comprises:
an illumination optical system that illuminates a reticle with light from a light source section;
a reticle stage system that is movable with the reticle mounted thereon;
a projection optical system that guides light from the reticle to a substrate;
a substrate stage system that is movable with the reticle mounted thereon; and
a substrate conveyance device that conveys the substrate to the substrate stage system,
wherein the substrate conveyance device comprises a supporting mechanism comprising a hand for holding the substrate by a suction mechanism and a support section for movably supporting the hand, and a control system for controlling the operation of the supporting mechanism, and
wherein, when the supporting mechanism and a mounting section are installed on two different reference platforms, the control system comprises a position adjustment sequence for the execution of a suction time monitoring processing in which the suction pressure of the suction mechanism is upward raised to a predetermined threshold value after the lifting of the hand from the standby position on the mounting section is initiated in a vacuum suction state and its driving time is monitored; an adjustment determining processing of determining whether or not the adjustment of the receiving position of the substrate is necessary based on the monitor time period that has been obtained by the suction time monitoring processing; and a position setting processing of automatically setting the receiving position to the position at which a tolerance range is satisfied if it has been determined in the adjustment determining processing that the monitor time period and the suction pressure of the suction mechanism are not in a predetermined tolerance range.

9. A substrate processing apparatus comprising:
a processing unit that performs predetermined processing for a substrate;
a conveyance unit that is supported independently from the processing unit and includes a conveyance hand capable of transferring the substrate from and to the processing unit;
a suction section that is provided either at the processing unit or the conveyance hand and is capable of suctioning the substrate under reduced pressure;
a detection section that detects pressure in the suction section;
a determination section that determines whether or not the adjustment of the position at which the substrate is transferred is necessary based on information, which is obtained by the detection section, relating to pressure changes during the transfer; and
an adjustment section that adjusts the position at which the transfer is performed if the determination section determines that the adjustment is necessary.
